(19) United States
(12) Patent Application Publication
(10) Pub. No.: US 2010/0323505 A1
(43) Pub. Date: Dec. 23, 2010

(54) METHOD FOR MANUFACTURING SEMICONDUCTOR DEVICE

(76) Inventors: Masao ISHIKAWA, Malta, NY (US); Katsunori Yahashi, Kanagawa-ken (JP); Tomoya Satonaka, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/818,005

(22) Filed: Jun. 17, 2010

(30) Foreign Application Priority Data
Jun. 18, 2009 (JP) 2009-145533

(51) Int. Cl. H01L 21/28

(52) U.S. Cl. 438/492; 257/E21.21

(57) ABSTRACT

In one embodiment, a method is disclosed for manufacturing a semiconductor device. The method can include forming a resist on a subject layer containing silicon. The method can etch the subject layer using the resist as a mask and with a gas containing a halogen element, which is introduced into a processing chamber. After the etching of the subject layer, the method can slim a planner size of the resist with oxygen gas and a gas containing a halogen element, which are introduced into the same processing chamber.

### CROSS-REFERENCE TO RELATED APPLICATIONS

This application is based upon and claims the benefit of priority from the prior Japanese Patent Application No. 2009-145533, filed on Jun. 18, 2009; the entire contents of which are incorporated herein by reference.

### FIELD

Embodiments described herein relate generally to a method for manufacturing a semiconductor device.

### BACKGROUND

Proposals have been made for a memory device with a stacked structure in which a plurality of conductive layers functioning as word electrodes or control gates are alternately stacked with insulating layers. For instance, JP-A 2007-266143 discloses a technique for three-dimensionally arranging memory cells by forming through holes (memory holes) in the aforementioned stacked structure, forming a charge storage layer on the inner wall of the hole, and then burying a silicon pillar in the hole. JP-A 2007-266143 also discloses formation of contact holes for connecting upper wirings to respective conductive layers in a single etching process by forming the end portion of the conductive layers in a staircase structure and using its step difference.

A possible method for forming the aforementioned staircase structure portion is, for instance, to form a resist on the stacked structure of the conductive layers and insulating layers and repeat, a plurality of times, resist slimming for reducing the planar size of this resist and etching of the conductive layers and insulating layers using the resist as a mask. It is desirable that these processes be continuously performed in the same processing chamber in view of processing efficiency. However, in that case, there is concern that the slimming width of the resist may vary for each process of resist slimming. JP-A 2007-266143 does not specifically describe such a method for repeating resist slimming and etching, and the associated variation of resist slimming width.

### BRIEF DESCRIPTION OF THE DRAWINGS

FIG. 1 is a schematic perspective view showing the configuration of a memory cell array in a semiconductor device according to an embodiment;

FIG. 2 is a schematic perspective view of one memory string in the memory cell array;

FIG. 3 is a schematic cross-sectional view of the relevant part along the YZ direction in FIG. 1.

FIG. 4 is an enlarged cross-sectional view of the relevant part in FIG. 3;

FIGS. 5A to 7C are schematic views of a method for forming a staircase structure portion of conductive layers in the semiconductor device according to the embodiment;

FIG. 8 is a graph showing the relationship between the flow rate of SF₆ at resist slimming and the resist slimming width;

FIGS. 9A to 9C are schematic views showing another example of the method for forming the staircase structure portion; and

FIG. 10 is a graph showing the relationship between the etching rates of a resist and an interference layer, and the flow rate of a gas containing fluorine introduced into a processing chamber.

### DETAILED DESCRIPTION

In one embodiment, a method is disclosed for manufacturing a semiconductor device. The method can include forming a resist on a subject layer containing silicon. The method can etch the subject layer using the resist as a mask and with a gas containing a halogen element, which is introduced into a processing chamber. After the etching of the subject layer, the method can slim a planner size of the resist with oxygen gas and a gas containing a halogen element, which are introduced into the same processing chamber.

Embodiments will now be described with reference to the drawings. Although the semiconductor is illustratively silicon in the following embodiments, semiconductors other than silicon may also be used.

The semiconductor device according to an embodiment includes a memory cell array with a plurality of memory cells three-dimensionally arranged therein, and a peripheral circuit formed around the memory cell array.

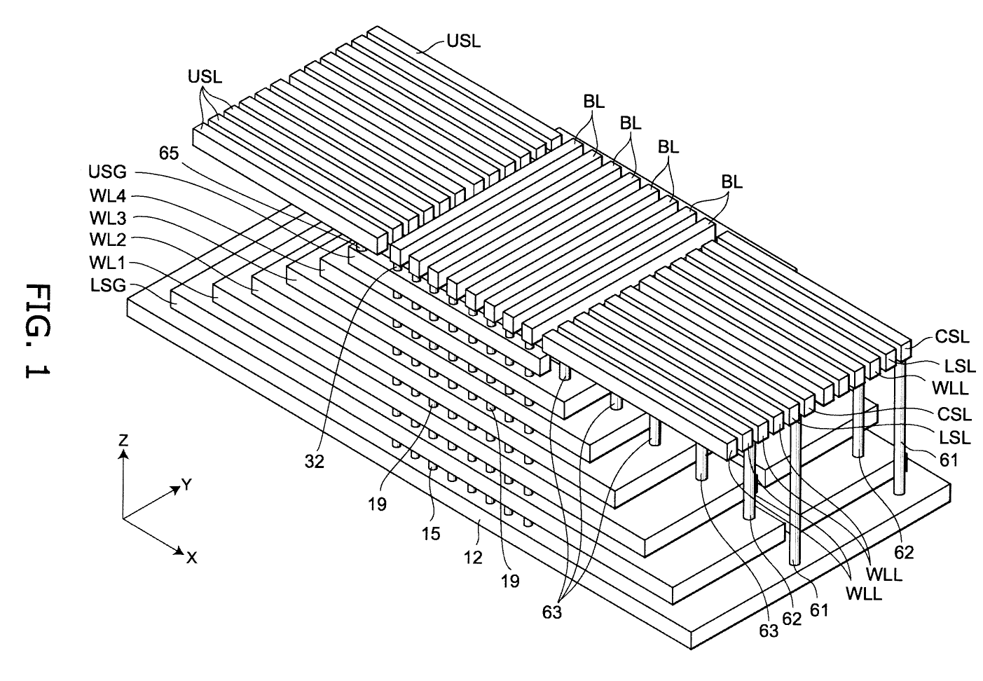

FIG. 1 is a schematic perspective view illustrating the configuration of the memory cell array.

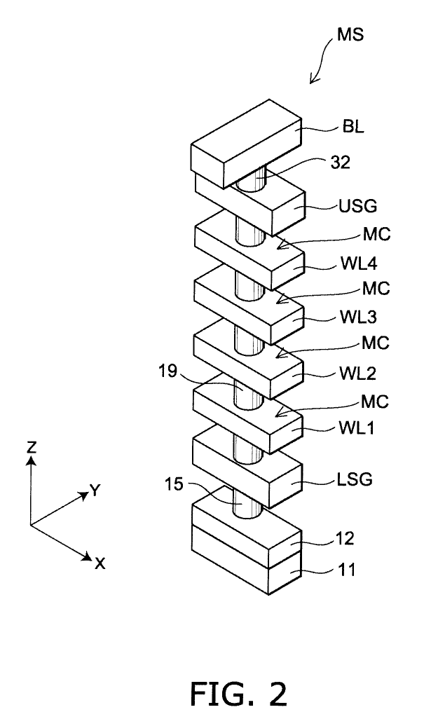

FIG. 2 is a schematic perspective view of one memory string MS composed of a plurality of memory cells MC connected in series in the stacking direction of the conductive layers WL1 to WL4.

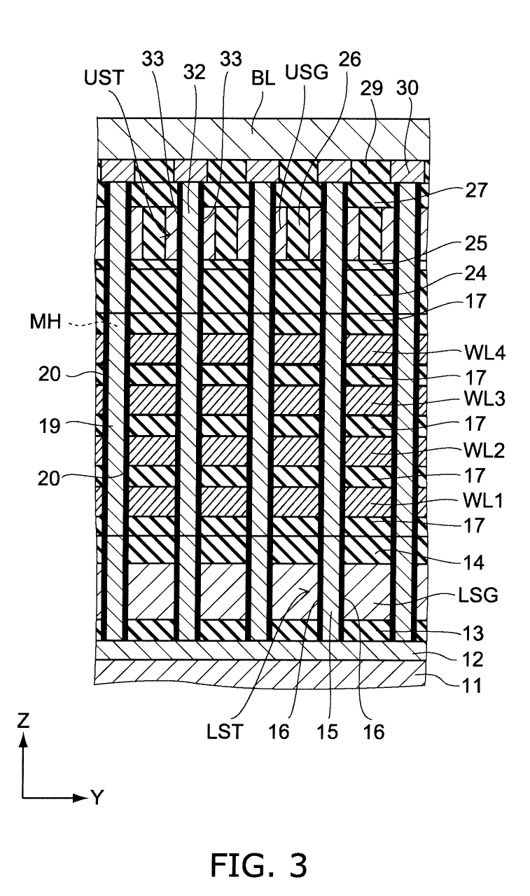

FIG. 3 is a schematic cross-sectional view of the memory cell array in the YZ direction in FIG. 1.

In FIGS. 1 and 2, for clarity of illustration, only the conductive portions are shown, and the insulating portions are not shown.

In this specification, an XYZ orthogonal coordinate system is introduced for convenience of description. In this coordinate system, the two directions parallel to the major surface of the substrate and orthogonal to each other are referred to as an X direction and a Y direction, and the direction orthogonal to both the X direction and the Y direction, that is, the stacking direction of a plurality of conductive layers WL1 to WL4, is referred to as a Z direction.

As shown in FIG. 3, a cell source 12 is provided on the substrate (e.g., silicon substrate) 11. The cell source 12 is a silicon layer doped with impurity and having conductivity. A lower select gate LSG is provided above the cell source 12 via an insulating layer 13. An insulating layer 14 is provided on the lower select gate LSG. The insulating layers 13 and 14 are layers containing silicon oxide or silicon nitride, and the lower select gate LSG is a silicon layer doped with impurity and having conductivity.

On the insulating layer 14 is provided a stacked body in which a plurality of insulating layers 17 and a plurality of conductive layers WL1 to WL4 are alternately stacked. The number of conductive layers WL1 to WL4 is arbitrary, and illustratively four in this embodiment. The insulating layer 17 contains silicon oxide. Each of the conductive layers WL1 to WL4 is a silicon layer doped with impurity and having conductivity.

A stopper layer (e.g., SiN layer) 24 is provided on the uppermost insulating layer 17 in the aforementioned stacked body. An upper select gate USG is provided above the stopper layer 24 via an insulating layer 25. An insulating layer 27 is provided on the upper select gate USG. The insulating layers 25 and 27 are layers containing silicon oxide or silicon nitride, and the upper select gate USG is a silicon layer doped with impurity and having conductivity.

As shown in FIG. 1, the conductive layers WL1 to WL4, the lower select gate LSG, and the cell source 12 are formed as plate-like layers parallel to the XY plane. The upper select gates USG are a plurality of wiring-like conductive members aligning in the X direction. As shown in FIG. 3, an insulating layer 26 is provided between each adjacent pair of the upper select gates USG. Here, it is also possible to use a configuration in which the lower select gate LSG is divided into a plurality like the upper select gates USG.

A plurality of memory holes aligning in the Z direction are formed in the aforementioned stacked body on the substrate 11. The memory holes are arranged in a matrix illustratively along the X direction and the Y direction.

As shown in FIG. 3, silicon pillars 15, 19, and 32 sequentially from the bottom, are buried as pillar-shaped semiconductor layers inside the memory hole MH. The silicon pillar 15 pierces the lower select gate LSG, the silicon pillar 19 pierces the plurality of conductive layers WL1 to WL4, and the silicon pillar 32 pierces the upper select gate USG.

The silicon pillars 15, 19, and 32 are formed from polycrystalline silicon or amorphous silicon. The silicon pillars 15, 19, and 32 are shaped like a pillar, such as a cylinder, aligning in the Z direction. The lower end of the silicon pillar 15 is connected to the cell source 12. The lower end of the silicon pillar 19 is connected to the silicon pillar 15, and the upper end of the silicon pillar 19 is connected to the silicon pillar 32.

An insulating layer 29 is provided on the insulating layer 27 on the upper select gate USG, and a plurality of bit lines BL aligning in the Y direction are provided on the insulating layer 29. Each of the bit lines BL is arranged so as to pass immediately above a corresponding sequence of the silicon pillars 32 arranged along the Y direction and is connected to the upper end of the silicon pillar 32 via a contact electrode 30 provided through the insulating layer 29.

As shown in FIG. 1, the upper select gate USG is connected to an upper select gate wiring USL via a contact electrode 65. The end portion of the stacked body, in which the cell source 12, the lower select gate LSG, and the plurality of conductive layers WL1 to WL4 are stacked, is processed into a staircase structure with the lower layer protruding to a greater extent in the X direction. In this staircase structure portion, the cell source 12 is connected to a cell source wiring CSL via a contact electrode 61, the lower select gate LSG is connected to a lower select gate wiring LSL via a contact electrode 62, and each of the conductive layers WL1 to WL4 is connected to a word line WLL via a contact electrode 63.

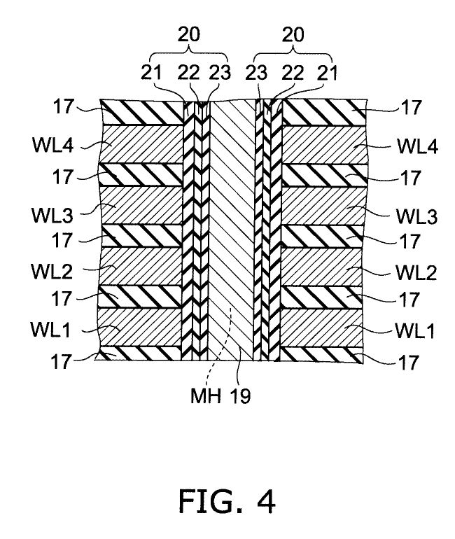

As shown in FIG. 3, an insulating film 20 illustratively having an oxide-nitride-oxide (ONO) structure, in which a silicon nitride film is sandwiched between a pair of silicon oxide films, is formed on the inner wall of the memory hole MH formed in the stacked body of the conductive layers WL1 to WL4 and the insulating layers 17. FIG. 4 shows an enlarged cross section of that portion.

The insulating film 20 has a structure in which a charge storage layer 22 is sandwiched between a first insulating film 21 and a second insulating film 23. The silicon pillar 19 is provided inside the second insulating film 23, and the second insulating film 23 is in contact with the silicon pillar 19. The first insulating film 21 is provided in contact with the conductive layers WL1 to WL4, and the charge storage layer 22 is provided between the first insulating film 21 and the second insulating film 23.

The silicon pillar 19 provided in the stacked body of the conductive layers WL1 to WL4 and the insulating layers 17 functions as a channel, the conductive layers WL1 to WL4 function as a control gate, and the charge storage layer 22 functions as a data storage layer for storing charge injected from the silicon pillar 19. That is, a memory cell having a structure in which the channel is surrounded by the control gate is formed at the intersection between the silicon pillar 19 and each of the conductive layers WL1 to WL4.

This memory cell has a charge trap structure. The charge storage layer 22 includes numerous traps operable to confine charges (electrons), and is illustratively made of silicon nitride film. The second insulating film 23 is illustratively made of silicon oxide film and serves as a potential barrier when a charge is injected from the silicon pillar 19 into the charge storage layer 22 or when a charge stored in the charge storage layer 22 diffuses into the silicon pillar 19. The first insulating film 21 is illustratively made of silicon oxide film and prevents charges stored in the charge storage layer 22 from diffusing into the conductive layers WL1 to WL4.

As shown in FIG. 2, as many memory cells MC as the number of conductive layers WL1 to WL4 are series connected in the Z direction around one silicon pillar 19 to constitute one memory string MS. Such memory strings MS are arranged in a matrix in the X direction and the Y direction, and thereby a plurality of memory cells MC are three-dimensionally arranged in the X direction, the Y direction, and the Z direction.

Referring to FIG. 3, on the inner wall of the hole formed in the stacked body composed of the lower select gate LSG and the overlying and underlying insulating layers 13 and 14, a gate insulating film 16 is formed in a tubular shape, and the silicon pillar 15 is buried inside it. Thus, this stacked body includes a lower select transistor LST with the silicon pillar 15 serving as a channel and the lower select gate LSG therearound serving as a gate electrode.

Furthermore, on the inner wall of the hole formed in the stacked body composed of the stopper layer 24, the upper select gate USG, and the overlying and underlying insulating layers 25 and 27, a gate insulating film 33 is formed in a tubular shape, and the silicon pillar 32 is buried inside it. Thus, this stacked body includes an upper select transistor UST with the silicon pillar 32 serving as a channel and the upper select gate USG therearound serving as a gate electrode.

A peripheral circuit, not shown, is formed on the same substrate 11 around the memory cell array described above. The peripheral circuit illustratively includes a driver circuit for applying a potential to the upper end portion of the silicon pillar 32 via the bit line BL, a driver circuit for applying a potential to the lower end portion of the silicon pillar 15 via the cell source wiring CSL and the cell source 12, a driver circuit for applying a potential to the upper select gate USG via the upper select gate wiring USL, a driver circuit for applying a potential to the lower select gate LSG via the lower select gate wiring LSL, and a driver circuit for applying a potential to each of the conductive layers WL1 to WL4 via the word line WLL.

The semiconductor device according to this embodiment is a nonvolatile semiconductor memory device allowing data to be erased and written electrically and freely and being capable of retaining its memory content even when powered off.

The X coordinate of the memory cell is selected by selecting the bit line BL, the Y coordinate of the memory cell is selected by selecting the upper select gate USG to turn the upper select transistor UST to the conducting or non-conducting state, and the Z coordinate of the memory cell is selected by selecting a word line WLL, or conductive layers WL1 to WL4. Then, data is stored by injecting electrons into the charge storage layer 22 of the selected memory cell. The data stored in the memory cell is read by passing a sense current in the silicon pillar 19, which passes through the memory cell.

In the semiconductor device of this embodiment, as shown in FIG. 1, the end portion of the conductive layers WL1 to WL4 outside the memory cell array region is processed into a staircase structure with the lower layer having a longer length from the memory cell array region. Thus, a plurality of contact holes for connecting the respective conductive layers WL1 to WL4 to the word lines WLL thereabove can be collectively formed by a single etching process.

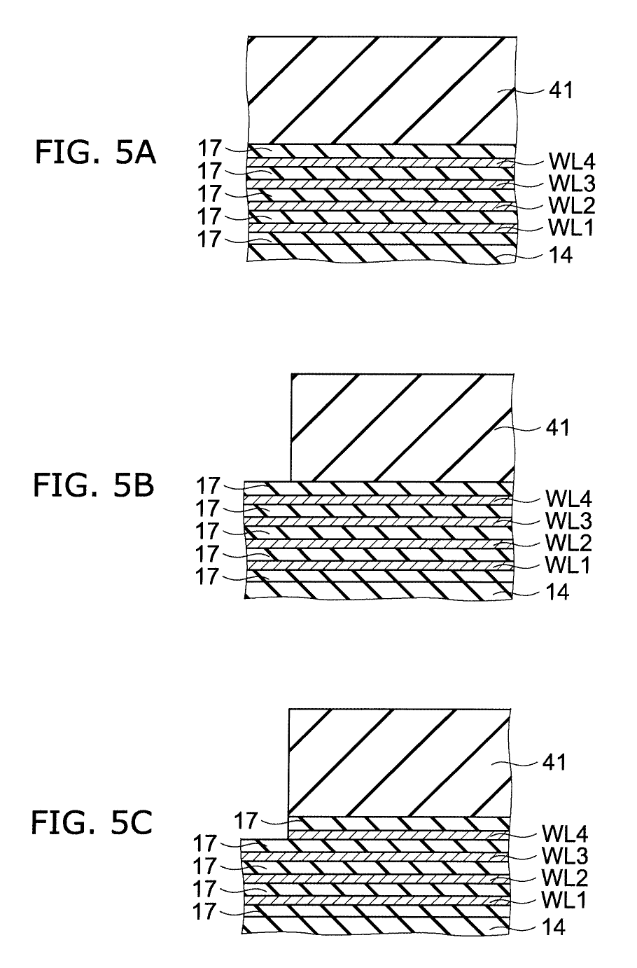

In the following, a method for forming the staircase structure portion of the conductive layers WL1 to WL4 in the semiconductor device according to this embodiment is described with reference to FIGS. 5A to 7C.

It is assumed that the lower select transistor LST, the transistors of the peripheral circuit and the like have already been formed on the substrate 11. A plurality of insulating layers 17 and a plurality of conductive layers WL1 to WL4 are alternately stacked on the insulating layer 14 on the lower select transistor LST illustratively by the chemical vapor deposition (CVD) process. The insulating layer 17 is a layer containing silicon oxide, and each of the conductive layers WL1 to WL4 is a silicon layer.

After the stacked body of the insulating layers 17 and the conductive layers WL1 to WL4 is formed, a process for forming the memory holes MH, the insulating film 20 including a charge storage layer, the silicon pillar 19 and the like shown in FIG. 3 is performed on the memory cell array region.

Subsequently, on the aforementioned stacked body, a resist 41 is formed as shown in FIG. 5A, and processing of a staircase structure portion is performed as follows. The resist contains an organic material and has the property of becoming soluble or insoluble in the developer in the portion irradiated with light or other energy radiation.

First, the resist 41 is subjected to lithography and development using a mask, not shown, and patterned so that the end of the resist 41 is located at a desired position as shown in FIG. 5B.

Next, the resist 41 is used as a mask to perform reactive ion etching (RIE) to remove the portion of the first insulating layer 17 from the top and the conductive layer WL4 therebelow exposed from the resist 41 as shown in FIG. 5C.

Specifically, the wafer with the aforementioned stacked body formed thereon is placed in a processing chamber. CHF₃ gas and BCl₃ gas, for instance, are first introduced into the processing chamber and then turned into plasma to etch the first insulating layer 17. Subsequently, HBr gas and Cl₂ gas, for instance, are introduced into the same processing chamber and then turned into plasma to etch the conductive layer WL4.

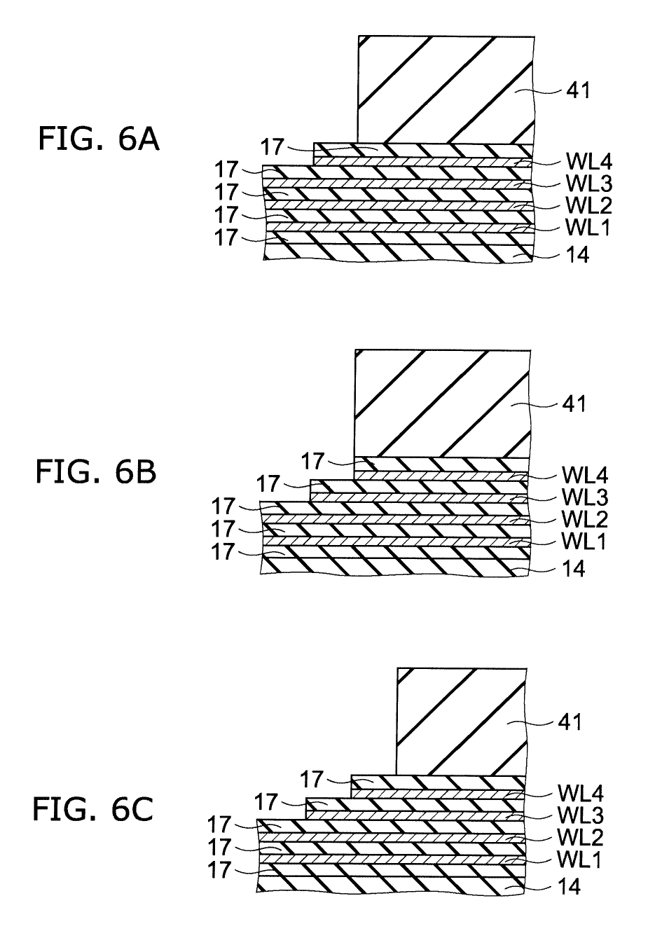

Subsequently, oxygen gas and a gas containing a halogen element are introduced into the same processing chamber and then turned into plasma to perform resist slimming for reducing the planar size of the resist 41 as shown in FIG. 6A. By this resist slimming, part of the surface of the first insulating layer 17 is newly exposed.

Subsequently, the slimmed resist 41 is used as a mask to perform RIE in the same processing chamber. As shown in FIG. 6B, this removes the second insulating layer 17 and the conductive layer WL3, which were located below the portion of the first insulating layer 17 and the conductive layer WL4 removed by the previous etching, and also removes the adjacent portion of the first insulating layer 17 and the conductive layer WL4 therebelow exposed from the resist 41.

Also in this process, CHF₃ gas and BCl₃ gas, for instance, are first introduced into the processing chamber and then turned into plasma to etch the insulating layers 17. Subsequently, HBr gas and Cl₂ gas, for instance, are introduced into the same processing chamber and then turned into plasma to etch the conductive layers WL3 and WL4.

After the process of FIG. 6B, subsequently, oxygen gas and a gas containing a halogen element are introduced into the same processing chamber and then turned into plasma to perform resist slimming for reducing the planar size of the resist 41 as shown in FIG. 6C. By this resist slimming, part of the surface of the first insulating layer 17 is newly exposed.

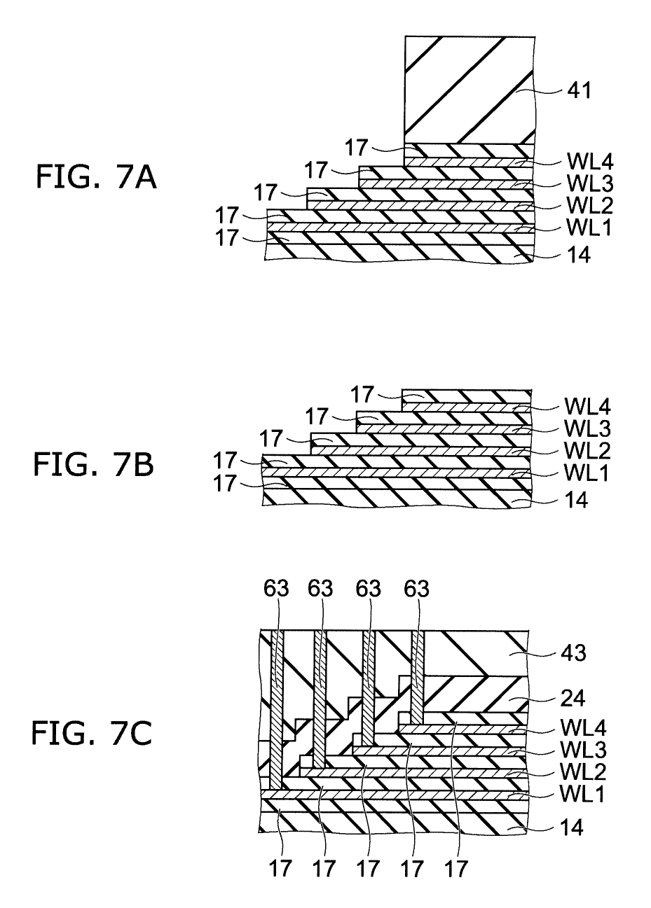

Subsequently, the slimmed resist 41 is used as a mask to perform RIE in the same processing chamber. As shown in FIG. 7A, this removes one layer of the insulating layers 17 exposed from the resist 41 and also removes one layer of the conductive layers WL2, WL3, and WL4 below these insulating layers 17.

Also in this process, CHF₃ gas and BCl₃ gas, for instance, are first introduced into the processing chamber and then turned into plasma to etch the insulating layer 17. Subsequently, HBr gas and Cl₂ gas, for instance, are introduced into the same processing chamber and then turned into plasma to etch the conductive layers WL2, WL3, and WL4.

Subsequently, the resist 41 is entirely removed, which results in the structure shown in FIG. 7B. That is, in this embodiment, the staircase structure shown in FIG. 7B is obtained by repeating the process of slimming the resist 41 and the process of etching one layer of the insulating layers 17 exposed from the resist 41 and one layer of the conductive layers WL2 to WL4 below the insulating layers 17.

The process of etching the insulating layers 17 and the conductive layers WL2 to WL4 and the process of slimming the resist 41 described above are continuously performed in the same processing chamber by switching gas species and the like introduced therein. That is, in the aforementioned sequence of processes, the wafer remains in the processing chamber, and a desired reduced-pressure atmosphere of a desired gas is maintained in the processing chamber without opening to the atmosphere. Thus, efficient processing can be performed.

In general, oxygen gas is used to remove a resist containing an organic material. This is based on the so-called ashing phenomenon in which oxygen gas is turned into plasma to oxidize and remove the resist. However, when the sequence of processes for processing the aforementioned staircase structure portion is performed in the same processing chamber using oxygen gas alone, there is a problem of variation in the reduction width (slimming width) of the planar size of the resist. Variation in the slimming width of the resist causes variation in the width of each step processed by using the resist as a mask and may affect the subsequent process and product quality.

The inventors have investigated the above problem and found that one of the causes is considered to be the fact that halogen elements contained in the gas used in etching the conductive layers WL3 to WL4 and the insulating layers 17 in the previous process remain in the processing chamber also at resist slimming. That is, at resist slimming, ashing by oxygen is dominant, but the resist may also be removed by the action of residual halogen elements activated or ionized by the plasma at resist slimming. In fact, the residual amount of halogen elements used in the previous process and existing in the processing chamber at resist slimming is considered infinitesimal. However, the residual amount is not intentionally controlled but variable, which may vary the resist slimming width.

Thus, in this embodiment, at resist slimming, a gas containing a halogen element is used in addition to oxygen gas as described above. The amount of oxygen introduced into the processing chamber is larger than that of the halogen element, and ashing by oxygen is dominant in the resist slimming.

The residual amount of halogen elements in the processing chamber at resist slimming is considered infinitesimal. A halogen element in a larger amount than this residual amount is introduced into the processing chamber at resist slimming. By desirably controlling the amount of the halogen element introduced at resist slimming, the resist slimming width due to the effect of halogen elements can be controlled. That is, the halogen element introduced in an intentionally controlled amount suppresses the effect of residual halogen elements remaining in an uncertain amount and improves the controllability of the resist slimming width.

In other words, in this embodiment, by resist slimming using a mixed gas of oxygen gas and a gas containing a halogen element, the resist slimming width can be stabilized, which serves to reduce variation in the width of each process of the staircase structure portion processed by using the slimmed resist 41 as a mask.

The resist slimming process in the aforementioned sequence of processes was performed under the following condition using a mixed gas of O₂ and SF₆, for instance. Then, stabilization of the resist slimming width was confirmed.

O₂ gas and SF₆ gas were introduced into the processing chamber at a flow rate of 200 sccm and 8 sccm, respectively, and the processing chamber pressure due to the mixed gas was maintained at 50 mTorr. An electromagnetic wave was generated by applying radio frequency power to transformer coupled plasma (TCP) electrodes provided outside the processing chamber and introduced into the processing chamber to excite the above mixed gas into plasma. The TCP electrodes were subjected to a radio frequency power of 1000 W. The wafer holder was grounded, and the wafer side was not biased. Furthermore, the temperature of the wafer was controlled at 60° C. by a temperature controlling mechanism, such as a heater, provided in the wafer holder.

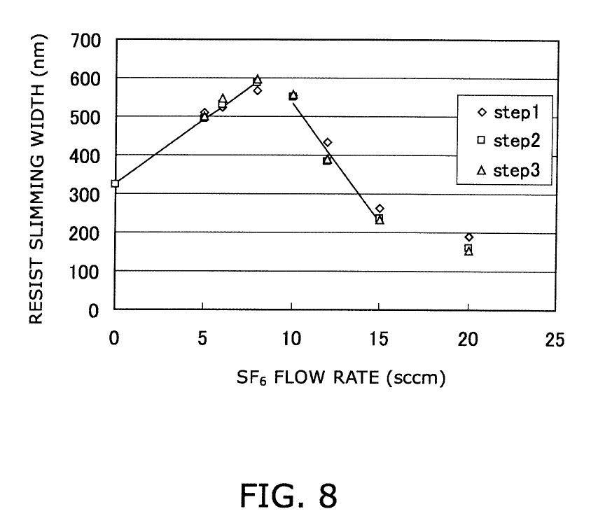

FIG. 8 is a graph showing the relationship between the flow rate (sccm) of SF₆ at resist slimming and the resist slimming width (nm). The condition is the same as the foregoing except that the flow rate of SF₆ was varied. FIG. 8 shows data obtained in three steps of resist slimming, step 1, step 2, and step 3.

As shown in the result of FIG. 8, the variation in resist slimming width relative to the variation in the flow rate of SF₆ gas is reduced when the flow rate of SF₆ gas is 7 to 9 sccm. If halogen elements used in the previous process remain, the processing chamber contains the residual halogen elements and the halogen element of SF₆ gas, or fluorine (F), newly introduced at resist slimming. Even if the residual halogen elements are different from fluorine, they are equivalent in being halogen elements, and the effect thereof on resist slimming is considered comparable to that of fluorine. Hence, the variation in the flow rate of SF₆ gas along the horizontal axis of the graph of FIG. 8 can be converted to the variation in the amount of halogen elements in the processing chamber. Thus, at resist slimming, even if the amount of halogen elements in the processing chamber is varied due to mixture of residual halogen elements in a trace amount relative to the intentionally introduced SF₆ gas, the variation of resist slimming width can be reduced by setting the flow rate of SF₆ gas to 7 to 9 sccm.

Here, O₂ gas is introduced at a flow rate of 200 sccm. That is, for 200 sccm of O₂ gas, the appropriate flow rate of SF₆ gas is 7 to 9 sccm. Hence, by setting the flow rate ratio of SF₆ gas in the mixed gas of O₂ gas and SF₆ gas to 3.4 to 4.3%, the effect of residual halogen elements can be suppressed, and the resist slimming width can be stabilized.

Furthermore, as shown in the result of FIG. 8, the resist slimming width is increased when the flow rate of SF₆ gas is 7 to 9 sccm. Hence, by setting the flow rate ratio of SF₆ gas in the mixed gas of O₂ gas and SF₆ gas to 3.4 to 4.3%, the resist slimming rate can be increased, and the processing time can be reduced.

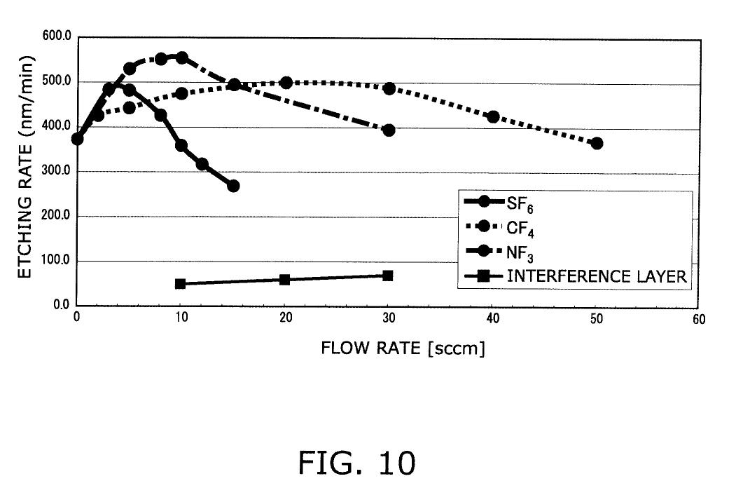

The relationship between the flow rate of a gas containing fluorine introduced into a processing chamber and the etching rate of a resist as shown in FIG. 10 is obtained by performing resist slimming with the same apparatus and the same condition as the case in which the data of FIG. 8 is obtained.

In this graph of FIG. 10, the horizontal axis represents each of the flow rates (sccm) of SF₆ gas, CF₄ gas, and NF₃ gas introduced into a processing chamber, and the vertical axis represents the etching rate (nm/min) of a resist. 200 sccm of O₂ gas is introduced into the processing chamber in addition to each gas containing the aforementioned fluorine.

The bold solid line represents the etching rate when using SF₆ gas, the dash line represents the etching rate when using CF₄ gas, and the dashed-dotted line represents the etching rate when using NF₃ gas, respectively.

As a result of FIG. 10, in the case where the flow rate of SF₆ gas is 3 to 5 sccm, i.e., in the case where the flow rate ratio of SF₆ gas is 1.4 to 2.4% in the mixed gas of O₂ gas and SF₆ gas, the etching rate of a resist can be maximized and stabilized. As a result of FIG. 8, in the case where the flow rate of SF₆ gas is 7 to 9 sccm, the resist slimming width, i.e., the etching rate of a resist can be maximized and stabilized. Although the flow rates of SF₆ gas in which the etching rate of a resist can be maximized and stabilized are different between FIG. 8 and FIG. 10, this is caused by the difference of disassociation due to variations in high-frequency radiation power efficiency and the like. Based on the result of FIG. 8 and the result of FIG. 10, it is desirable to set the flow rate ratio of SF₆ gas in the mixed gas of O₂ gas and SF₆ gas introduced into the processing chamber to 1.4 to 4.3%.

In this embodiment, the gas introduced at resist slimming is not limited to SF₆, but may be other fluorine-containing gases, or those containing a halogen element other than fluorine. For instance, NF₃ was used as a gas containing a halogen element and added to O₂, and it was confirmed that the resist slimming width can be controlled by introducing NF₃, just like SF₆.

In the case of NF₃ gas as well, an appropriate flow rate can be derived on the basis of the result of FIG. 10.

The flow rate of SF₆ gas is about 4 sccm when the resist etching rate indicates its peak. In contrast, the flow rate of NF₃ gas is about double the flow rate of SF₆ gas when the resist etching rate indicates its peak. It can be considered that six F atoms are dissociated from one molecule of the compound SF₆ in plasma and three F atoms are dissociated from one molecule of the compound NF₃ in plasma. Therefore, the same effect as the case of SF₆ gas can be realized by setting the flow rate of NF₃ gas about double the flow rate of SF₆ gas. Hence, it is desirable to set the flow rate ratio of NF₃ gas in the mixed gas of O₂ gas and NF₃ gas introduced into the processing chamber to 2.8 to 8.6%.

It is confirmed that the resist slimming width can be controlled similarly by introducing CF₄ when using CF₄ added to O₂ as a gas containing halogen elements.

In the case of CF₄ gas as well, an appropriate flow rate can be derived on the basis of the result of FIG. 10.

The flow rate of SF₆ gas is about 4 sccm when the resist etching rate indicates its peak. In contrast, the flow rate of CF₄ gas is about six times the flow rate of SF₆ gas when the resist etching rate indicates its peak. Therefore, the same effect as the case of SF₆ gas can be realized by setting the flow rate of CF₄ gas about six times the flow rate of SF₆ gas. Hence, it is desirable to set the flow rate ratio of CF₄ gas in the mixed gas of O₂ gas and CF₄ gas introduced into the processing chamber to 8.4 to 25.8%. In the case of CF₄ gas, the range of the flow rate that obtains the same effect as the case of SF₆ gas is not simply the ratio, i.e., 6/4 times, which makes the number of F (fluorine) atoms equal. It is considered that this is because of the effect of the deposition of C (carbon).

As described above, after the staircase structure portion shown in FIG. 7B is formed, as shown in FIG. 7C, a silicon nitride-based stopper layer 24 is formed so as to cover the staircase structure portion, and a silicon oxide-based interlayer insulating layer 43 is further formed on the stopper layer 24. These are formed illustratively by the CVD process. The interlayer insulating layer 43 shown in FIG. 7C corresponds to part of the insulating layer in the stacked body including the upper select transistor UST shown in FIG. 3.

After the stopper layer 24 and the interlayer insulating layer 43 are formed, a plurality of contact holes punched through the interlayer insulating layer 43, the stopper layer 24, and the insulating layer 17 below the stopper layer 24 and reaching the corresponding conductive layers WL1 to WL4 are collectively formed. After these contact holes are formed, a conductive material, such as tungsten, is buried in each of the contact holes to form a contact electrode 63 as shown in FIG. 7C.

Each of the conductive layers WL1 to WL4 is electrically connected to the upper word line WLL shown in FIG. 1 via the contact electrode 63 provided on the staircase structure portion.

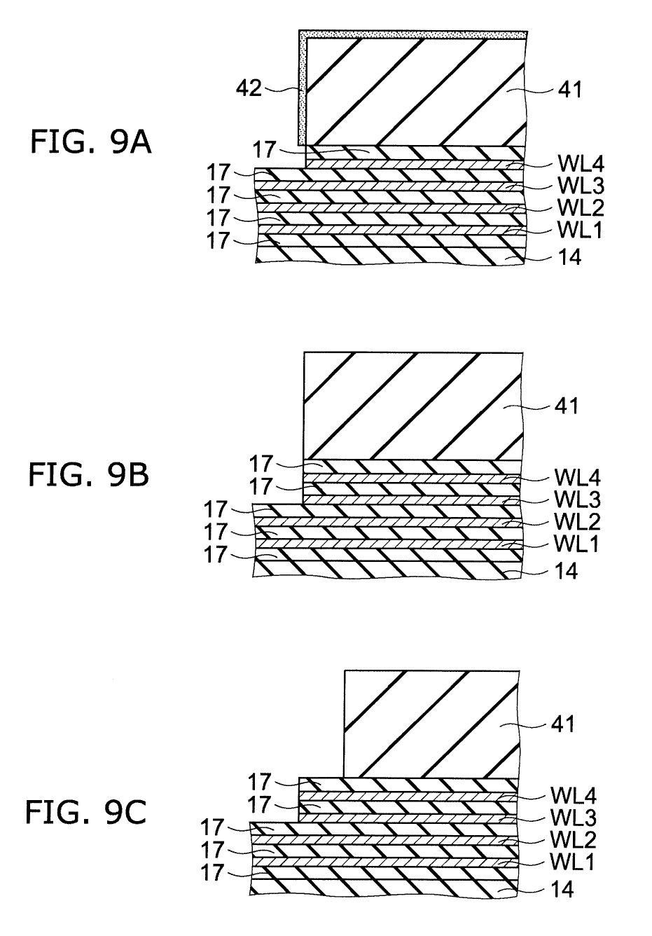

Next, another example of the method for forming the aforementioned staircase structure portion is described with reference to FIGS. 9A to 9C.

During RIE of the insulating layers 17 and the conductive layers WL1 to WL4, a reaction product resulting from the constituent element of the insulating layers 17 and the conductive layers WL1 to WL4, such as silicon, may be generated and attached to the upper surface and sidewall of the resist 41. The product is relatively resistant to oxygen gas serving primarily for resist removal in the slimming of the resist 41, and functions as an interference layer 42 interfering with the progress of etching of the resist 41.

Depending on the etching apparatus used, due to its evacuation characteristics, the film thickness of the interference layer 42 formed in the center portion of the wafer tends to be larger than the film thickness of the interference layer 42 formed in the edge portion. Hence, at resist slimming, the interference layer 42 in the edge portion of the wafer vanishes earlier than the interference layer 42 in the center portion, and resist slimming proceeds in the edge portion, while the interference layer 42 still remains in the center portion of the wafer. Consequently, in the wafer surface, the slimming width of the resist 41 may vary between the center portion and the edge portion and cause the width of each step of the staircase structure portion to vary in the wafer surface. Also, the consumption of the film thickness of the resist in the longitudinal direction is large due to the interference layer 42 attached to the side wall of the resist 41 when performing a desired slimming, and therefore, a lack of the film thickness of the resist 41 may occur in the case where multiple steps are patterned.

Thus, in the example described below, after etching the insulating layers 17 and the conductive layers WL1 to WL4 and before slimming the resist 41, the process of removing the interference layer 42 is performed. The difference between the etching rate of the resist 41 and the etching rate of the interference layer 42 under the etching condition for removing the interference layer 42 is small as compared to the etching condition for resist slimming.

FIG. 9A shows the state in which the uppermost insulating layer 17 and the conductive layer WL4 therebelow, for instance, have been etched by using the resist 41 as a mask. The reaction product generated during the etching is formed as the interference layer 42 on the upper surface and sidewall of the resist 41.

After the insulating layer 17 and the conductive layer WL4 are etched, O₂ gas and a fluorine-containing gas are introduced into the processing chamber. For instance, O₂ gas and NF₃ gas are introduced into the processing chamber at a flow rate of 200 sccm and 30 sccm, respectively, and the processing chamber pressure due to the mixed gas is maintained at 50 mTorr. The condition except the flow rate of the fluorine-containing gas is the same as that at resist slimming. By this plasma etching, the interference layer 42 is removed (FIG. 9B).

Subsequently, O₂ gas and NF₃ gas are introduced into the processing chamber at a flow rate of 200 sccm and 10 sccm, respectively, and resist slimming is performed (FIG. 9C). At this resist slimming, the amount of NF₃ gas introduced into the processing chamber is set smaller than at the removal of the interference layer 42. That is, the partial pressure of NF₃ gas in the processing chamber at the removal of the interference layer 42 is higher than the partial pressure of NF₃ gas in the processing chamber at resist slimming.

Subsequently, RIE of the stacked body using the slimmed resist 41 as a mask, removal of the interference layer 42, and resist slimming are repeated a necessary number of times.

A graph of FIG. 10 showing with the combination of square points and the solid line is the etching rate of the interference layer 42. The etching rate of the interference layer 42 is substantially the same in the case where the mixed gas of O₂ gas and NF₃ gas is used, in the case where the mixed gas of O₂ gas and SF₆ gas is used, and in the case where the mixed gas of O₂ gas and CF₄ gas is used. These results are summarized and shown in FIG. 10. The flow rate of O₂ gas is 200 sccm in any of the cases.

As shown in the graph of FIG. 10, as the flow rate of NF₃ gas increases, the slimming rate of the resist 41 as represented by the dashed-dotted line decreases, while the etching rate of the interference layer 42 remains nearly flat. Thus, by increasing the flow rate of NF₃ gas more than during resist slimming, the interference layer 42 can be removed while the consumption of the resist 41 is suppressed.

Hence, at resist slimming, the flow rate of NF₃ gas is relatively decreased to increase the etching rate of the resist 41 to enhance the processing efficiency. On the other hand, at the removal of the interference layer 42, the flow rate of NF₃ gas is relatively increased to suppress the etching of the resist 41 to efficiently remove the interference layer 42.

In other words, the flow rate (e.g., 30 sccm) of NF₃ gas set at the removal of the interference layer 42 makes the etching rate of the resist 41 lower than the flow rate (e.g., 10 sccm) of NF₃ gas set at the slimming of the resist 41.

For efficiently removing the interference layer 42 while suppressing the etching of the resist 41, it is desirable to set the flow rate of NF₃ gas introduced into the processing chamber at the removal of the interference layer 42, for instance, three times or more the flow rate of NF₃ gas introduces into the processing chamber at the slimming of the resist 41.

If a gas used at the removal of the interference layer 42 and a gas used at the slimming of the resist 41 are the same gases, the number of gas species to be prepared is decreased, and the cost can be reduced.

By slimming the resist 41 after removing the interference layer 42, variation in resist slimming width due to variation in the thickness of the interference layer 42 can be suppressed. Consequently, the width of each step of the aforementioned staircase structure portion can be suppressed from varying between the center portion and the edge portion in the wafer surface.

As a comparative example, without removing the interference layer 42, O₂ gas and NF₃ gas were introduced into the processing chamber at a flow rate of 200 sccm and 10 sccm, respectively, to perform slimming of the resist 41. Then, there occurred a difference of step width of approximately 100 nm between the center portion and the edge portion in the wafer. In contrast, after removing the interference layer 42, O₂ gas and NF₃ gas were introduced into the processing chamber at a flow rate of 200 sccm and 30 sccm, respectively, with the other conditions being the same as at resist slimming, to perform resist slimming under the same condition as the above comparative example. Then, the difference of step width between the center portion and the edge portion in the wafer was reduced to approximately 20 nm.

Also in the case of SF₆ gas as shown in FIG. 10, as the flow rate of SF₆ gas increases, the slimming rate of the resist 41 as represented by the bold solid line decreases, while the etching rate of the interference layer 42 remains nearly flat. Thus, by increasing the flow rate of SF₆ gas more than during resist slimming, the interference layer 42 can be removed while the consumption of the resist 41 is suppressed.

Hence, at resist slimming, the flow rate of SF₆ gas is relatively decreased to increase the etching rate of the resist 41 to enhance the processing efficiency. On the other hand, at the removal of the interference layer 42, the flow rate of SF₆ gas is relatively increased to suppress the etching of the resist 41 to efficiently remove the interference layer 42.

In other words, the flow rate of SF₆ gas set at the removal of the interference layer 42 makes the etching rate of the resist 41 lower than the flow rate of SF₆ gas set at the slimming of the resist 41.

For efficiently removing the interference layer 42 while suppressing the etching of the resist 41, it is desirable to set the flow rate of SF₆ gas introduced into the processing chamber at the removal of the interference layer 42, for instance, three times or more the flow rate of SF₆ gas introduced into the processing chamber at the slimming of the resist 41.

Also in the case of CF₄ gas as shown in FIG. 10, as the flow rate of CF₄ gas increases, the slimming rate of the resist 41 as represented by the dash line decreases, while the etching rate of the interference layer 42 remains nearly flat. Thus, by increasing the flow rate of CF₄ gas more than during resist slimming, the interference layer 42 can be removed while the consumption of the resist 41 is suppressed.

Hence, at resist slimming, the flow rate of CF₄ gas is relatively decreased to increase the etching rate of the resist 41 to enhance the processing efficiency. On the other hand, at the removal of the interference layer 42, the flow rate of CF₄ gas is relatively increased to suppress the etching of the resist 41 to efficiently remove the interference layer 42.

In other words, the flow rate of CF₄ gas set at the removal of the interference layer 42 makes the etching rate of the resist 41 lower than the flow rate of CF₄ gas set at the slimming of the resist 41.

For efficiently removing the interference layer 42 while suppressing the etching of the resist 41, it is desirable to set the flow rate of CF₄ gas introduced into the processing chamber at the removal of the interference layer 42, for instance, three times or more the flow rate of CF₄ gas introduces into the processing chamber at the slimming of the resist 41.

The shape of the silicon pillar in the memory cell array is not limited to a cylinder, but may be a prism. Furthermore, the invention is not limited to burying a silicon pillar entirely in the memory hole. As an alternative structure, a silicon film may be formed in a tubular shape only at the portion in contact with the insulating film including the charge storage layer, and an insulator may be buried inside it. Furthermore, the insulating film structure between the conductive layer and the silicon pillar is not limited to the oxide-nitride-oxide (ONO) structure, but may be a two-layer structure of a charge storage layer and a gate insulating film, for instance.

While certain embodiments have been described, these embodiments have been presented by way of example only, and are not intended to limit the scope of the inventions. Indeed, the novel methods and devices described herein may be embodied in a variety of other forms; furthermore, various omissions, substitutions and changes in the form of the methods and devices described herein may be made without departing from the spirit of the inventions. The accompanying claims and their equivalents are intended to cover such forms or modification as would fall within the scope and spirit of the inventions.

1. A method for manufacturing a semiconductor device, comprising:
forming a resist on a subject layer containing silicon;
introducing a gas containing a halogen element into a processing chamber and etching the subject layer with the gas containing the halogen element by using the resist as a mask; and
after the etching of the subject layer, introducing oxygen gas and a gas containing a halogen element into the same processing chamber and slimming a planar size of the resist with the oxygen gas and the gas containing the halogen element.

2. The method according to claim 1, wherein the halogen element contained in the gas used in the slimming of the resist is fluorine.

3. The method according to claim 2, wherein a mixed gas of O₂ and SF₆ is used in the slimming of the resist, and a flow rate ratio of the SF₆ in the mixed gas introduced into the processing chamber is set to 1.4 to 4.3%.

4. The method according to claim 2, wherein a mixed gas of O₂ and NF₃ is used in the slimming of the resist, and a flow rate ratio of the NF₃ in the mixed gas introduced into the processing chamber is set to 2.8 to 8.6%.

5. The method according to claim 2, wherein a mixed gas of O₂ and CF₄ is used in the slimming of the resist, and a flow rate ratio of the CF₄ in the mixed gas introduced into the processing chamber is set to 8.4 to 25.8%.

6. The method according to claim 1, wherein the oxygen is introduced into the processing chamber in a larger amount than the halogen element in the slimming of the resist.

7. The method according to claim 1, further comprising:
removing a interference layer with oxygen gas and a gas containing a fluorine after the etching of the subject layer and before the slimming of the resist, the interference layer including silicon being formed on a sidewall of the resist in the etching of the subject layer.

8. The method according to claim 7, wherein
the halogen element contained in the gas used in the slimming of the resist is fluorine, and
an amount of the fluorine introduced into the processing chamber in the removing of the interference layer is larger than an amount of the fluorine introduced into the processing chamber in the slimming of the resist.

9. The method according to claim 8, wherein a gas identical to the gas used in the slimming of the resist is used in the removing of the interference layer.

10. The method according to claim 9, wherein a flow rate of the gas containing the fluorine introduced into the processing chamber in the removing of the interference layer is three times or more a flow rate of the gas containing the fluorine introduced into the processing chamber in the slimming of the resist.

11. The method according to claim 7, wherein
NF₃ gas is used in both the removing of the interference layer and the slimming of the resist; and
a flow rate of NF₃ gas set in the removing of the interference layer makes an etching rate of the resist lower than a flow rate of NF₃ gas set in the slimming of the resist.

12. The method according to claim 7, wherein
SF₆ gas is used in both the removing of the interference layer and the slimming of the resist; and
a flow rate of SF₆ gas set in the removing of the interference layer makes an etching rate of the resist lower than a flow rate of SF₆ gas set in the slimming of the resist.

13. The method according to claim 7, wherein
CF₄ gas is used in both the removing of the interference layer and the slimming of the resist; and
a flow rate of CF₄ gas set in the removing of the interference layer makes an etching rate of the resist lower than a flow rate of CF₄ gas set in the slimming of the resist.

14. The method according to claim 1, wherein the subject layer has a structure including a plurality of insulating layers and conductive layers being alternately stacked.

15. The method according to claim 14, wherein the insulating layers contain silicon oxide.

16. The method according to claim 14, wherein the conductive layers are silicon layers.

17. The method according to claim 14, further comprising:
forming a memory hole punched through a stacked structure of the insulating layers and the conductive layers;
forming an insulating film including a charge storage layer on a sidewall of the memory hole; and
forming a semiconductor layer inside the insulating film in the memory hole.

18. The method according to claim 14, wherein the slimming the resist and etching one layer of the insulating layers and one layer of the conductive layers exposed from the resist are repeated to process the conductive layers into a staircase structure.

19. The method according to claim 18, further comprising:
forming an interlayer insulating layer above the staircase structure portion of the conductive layers;
forming contact holes punched through the interlayer insulating layer and reaching the conductive layers respectively; and
providing a conductive material in the contact holes.

20. The method according to claim 18, further comprising:
forming a stopper layer containing silicon nitride on the staircase structure portion of the conductive layers;
forming an interlayer insulating layer containing silicon oxide on the stopper layer;
forming contact holes punched through the interlayer insulating layer and the stopper layer and reaching the conductive layers respectively; and
providing a conductive material in the contact holes.
